(19) United States
(12) Patent Application Publication
(10) Pub. No.: US 2023/0378039 A1
(43) Pub. Date: Nov. 23, 2023

(54) SEMICONDUCTOR PACKAGE AND METHODS OF MANUFACTURING

(71) Applicant: Taiwan Semiconductor Manufacturing Company, Ltd., Hsinchu (TW)

(72) Inventors: Hsien-Wei CHEN, Hsinchu City (TW); Meng-Liang LIN, Hsinchu (TW); Li-Ling LIAO, Hsinchu City (TW); Shin-Puu JENG, Hsinchu (TW)

(21) Appl. No.: 17/664,538

(22) Filed: May 23, 2022

(51) Int. Cl. H01L 23/498; H01L 25/065; H01L 23/00; H01L 23/31; H01L 23/64; H01L 21/48

(52) U.S. Cl. CPC H01L 23/49822; H01L 25/0655; H01L 24/16; H01L 23/3128; H01L 23/3135; H01L 23/49838; H01L 23/642; H01L 21/4853; H01L 21/4857; H01L 2224/16227; H01L 2924/18161; H01L 2924/19041; H01L 2924/19103

(57) ABSTRACT

Some implementations herein describe a semiconductor package. The semiconductor package, which may correspond to a high-performance computing semiconductor package, includes an interposer. The interposer includes tapered interconnect structures formed using a laser plug process. The tapered interconnect structures may include a length that is lesser relative to a length of the column-shaped interconnect structures formed using a through-silicon via process. Such a length reduces a thickness of the interposer and reduces a length of electrical connections through the interposer. In this way, a signal integrity may be increased and parasitics of the semiconductor package including the tapered interconnect structures may be reduced to increase a performance of the semiconductor package. Additionally, the reduced thickness of the interposer may reduce an overall thickness of the semiconductor package to save space consumed by the semiconductor package in a computing system.

### BACKGROUND

A high-performance computing (HPC) semiconductor package may include one or more integrated circuit (IC) dies, or chips, from a semiconductor wafer, such as a system-on-chip (SoC) IC die, a dynamic random access memory (DRAM) IC die, or a high bandwidth memory (HBM) IC die. The HPC semiconductor package may include an interposer that provides an interface between the one or more IC dies and a substrate. The HPC semiconductor package may further include one or more interconnect structures to provide electrical connectivity for signaling between the one or more IC dies, the interposer, and the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example implementation of a semiconductor package described herein.

FIGS. 3, 4, and 5A-5C are diagrams of example implementations described herein.

FIG. 6 is a diagram of example components of one or more devices of FIG. 1 described herein.

FIG. 7 is a flowchart of a process associated with forming a semiconductor package described herein.

FIGS. 8A-8E are diagrams of an example implementation described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package, such as an HPC semiconductor package, may include an interposer that provides an interface between one or more IC dies and a substrate. The HPC semiconductor package further includes one or more interconnect structures to provide electrical connectivity for signaling between the one or more IC dies, the interposer, and the substrate.

The interposer may include column-shaped interconnect structures passing through a silicon substrate that are formed using a through-silicon vertical interconnect access process (e.g., a through-silicon via (TSV) process). The TSV process may include multiple processing steps, including use of a temporary carrier and backside processing/thinning of the silicon substrate for the column-shaped interconnect structures to protrude through the silicon substrate. For mechanical robustness and to accommodate the TSV process, a thickness of the silicon substrate may exceed a magnitude that is adequate to form one or more electrical connections (e.g., interconnect structures) through the silicon substrate to have targeted electrical performance.

For example, and due to the thickness of the silicon substrate used during the TSV process, the column-shaped interconnect structures may include one or more dimensional properties, such as a high aspect ratio, a length, or a diameter, that reduce a signal integrity and/or increase parasitics of the HPC semiconductor package. As an example, a column-shaped interconnect structure formed using a TSV process may include a length of up to approximately 100 microns. Such a length may increase an overall height of the HPC semiconductor package to consume extra space in a computing system including the HPC semiconductor package.

Some implementations herein describe a semiconductor package. The semiconductor package, which may correspond to an HPC semiconductor package, includes an interposer. The interposer includes tapered interconnect structures formed using a laser plug process. The laser plug process may accommodate forming the interposer to a thickness that is lesser relative to an interposer formed using a TSV process. Due to the lesser thickness, the tapered interconnect structures may include a length that is lesser relative to a length of the column-shaped interconnect structures formed using the TSV process. For example, the tapered interconnect structures may have a length of less than approximately 50 microns. Such a length reduces a length of electrical connections through the interposer.

In this way, a signal integrity may be increased and parasitics of the semiconductor package including the tapered interconnect structures may be reduced to increase a performance of the semiconductor package. Additionally, the reduced thickness of the interposer may reduce an overall thickness of the semiconductor package to save space consumed by the semiconductor package in a computing system.

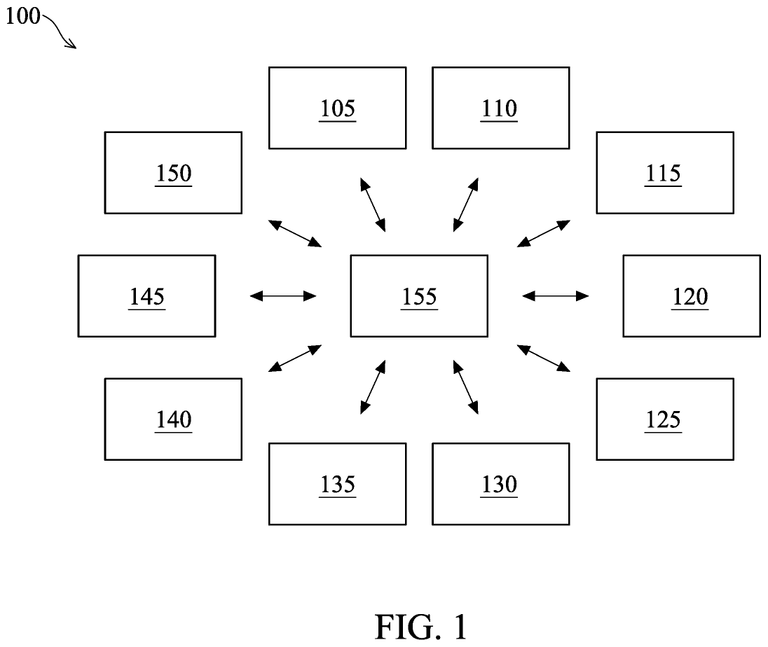

FIG. 1 is a diagram of an example environment 100 in which systems and/or methods described herein may be implemented. As shown in FIG. 1, environment 100 may include a plurality of semiconductor processing tool sets 105-150 and a transport tool set 155. The plurality of semiconductor processing tool sets 105-150 may include a redistribution layer (RDL) tool set 105, a planarization tool set 110, an connection tool set 115, an automated test equipment (ATE) tool set 120, a singulation tool set 125, a die-attach tool set 130, an encapsulation tool set 135, a printed circuit board (PCB) tool set 140, a surface mount (SMT) tool set 145, and a finished goods tool set 150. The semiconductor processing tool sets 105-150 of example environment 100 may be included in one or more facilities, such as a semiconductor clean or semi-clean room, a semiconductor foundry, a semiconductor processing facility, an outsourced assembly and test (OSAT) facility, and/or a manufacturing facility, among other examples. It is understood that each of semiconductor processing tool sets 105-150 may be optional in environment 100. In some implementations, the semiconductor processing tool sets 105-150, and operations performed by the semiconductor processing tool sets 105-150, are distributed across multiple facilities. Additionally, or alternatively, one or more of the semiconductor processing tool sets 105-150 may be subdivided across the multiple facilities. Sequences of operations performed by the semiconductor processing tool sets 105-150 may vary based on a type of the semiconductor package or a state of completion of the semiconductor package.

One or more of the semiconductor processing tool sets 105-150 may perform a combination of operations to assemble a semiconductor package (e.g., attach one or more IC dies to a substrate, where the substrate provides an external connectivity to a computing device, among other examples). Additionally, or alternatively, one or more of the semiconductor processing tool sets 105-150 may perform a combination of operations to ensure a quality and/or a reliability of the semiconductor package (e.g., test and sort the one or more IC dies, and/or the semiconductor package, at various stages of manufacturing).

The semiconductor package may correspond to a type of semiconductor package. For example, the semiconductor package may correspond to a flipchip (FC) type of semiconductor package, a ball grid array (BGA) type of semiconductor package, a multi-chip package (MCP) type of semiconductor package, or a chip scale package (CSP) type of semiconductor package. Additionally, or alternatively, the semiconductor package may correspond to a plastic leadless chip carrier (PLCC) type of semiconductor package, a system-in-package (SIP) type of semiconductor package, a ceramic leadless chip carrier (CLCC) type of semiconductor package, or a thin small outline package (TSOP) type of semiconductor package, among other examples.

The RDL tool set 105 includes one or more tools capable of forming one or more layers and patterns of materials (e.g., dielectric layers, conductive redistribution layers, and/or vertical interconnect access structures (vias), among other examples) on a semiconductor substrate (e.g., a semiconductor wafer, among other examples). The RDL tool set 105 may include a combination of one or more photolithography tools (e.g., a photolithography exposure tool, a photoresist dispense tool, a photoresist develop tool, among other examples), a combination of one or more etch tools (e.g., a plasma-based etch tool, a dry-etch tool, or a wet-etch tool, among other examples), a laser tool, and one or more deposition tools (e.g., a chemical vapor deposition (CVD) tool, a physical vapor deposition (PVD) tool, an atomic layer deposition (ALD) tool, a spin coating tool, and/or a plating tool, among other examples). The RDL tool set 105 may further include a bonding/debonding tool for joining, and/or separating, semiconductor substrates (e.g., semiconductor wafers). In some implementations, the example environment 100 includes a plurality of types of such tools as part of RDL tool set 105.

The planarization tool set 110 includes one or more tools that are capable of polishing or planarizing various layers of the semiconductor substrate (e.g., the semiconductor wafer). The planarization tool set 110 may also include tools capable of thinning the semiconductor substrate. The planarization tool set 110 may include a chemical mechanical planarization (CMP) tool, a grinding tool, a lapping tool, and a taping tool, among other examples. In some implementations, the example environment 100 includes a plurality of types of such tools as part of the planarization tool set 110.

The connection tool set 115 includes one or more tools that are capable of forming interconnect structures (e.g., electrically-conductive structures) as part of the semiconductor package. The interconnect structures formed by the connection tool set 115 may include a wire, a stud, a pillar, a bump, or a solderball, among other examples. The interconnect structures formed by the connection tool set 115 may include materials such as a gold (Au) material, a copper (Cu) material, a silver (Ag) material, a nickel (Ni) material, a tin (Sn) material, or a palladium (Pd) material, among other examples. The connection tool set 115 may include a bumping tool, a wirebond tool, or a plating tool, among other examples. In some implementations, the example environment 100 includes a plurality of types of such tools as part of the connection tool set 115.

The ATE tool set 120 includes one or more tools that are capable of testing a quality and a reliability of the one or more IC dies and/or the semiconductor package (e.g., the one or more IC dies after encapsulation). The ATE tool set 120 may perform wafer testing operations, known good die (KGD) testing operations, semiconductor package testing operations, or system-level (e.g., a circuit board populated with one or more semiconductor packages and/or one or more IC dies) testing operations, among other examples. The ATE tool set 120 may include a parametric tester tool, a speed tester tool, and/or a burn-in tool, among other examples. Additionally, or alternatively, the ATE tool set 120 may include a prober tool, probe card tooling, test interface tooling, test socket tooling, a test handler tool, burn-in board tooling, and/or a burn-in board loader/unloader tool, among other examples. In some implementations, the example environment 100 includes a plurality of types of such tools as part of the ATE tool set 120.

The singulation tool set 125 includes one or more tools that are capable of singulating (e.g., separating, removing) the one or more IC dies or the semiconductor package from a carrier. For example, the singulation tool set 125 may include a dicing tool, a sawing tool, or a laser tool that cuts the one or more IC dies from the semiconductor substrate. Additionally, or alternatively, the singulation tool set 125 may include a trim-and-form tool that excises the semiconductor package from a leadframe. Additionally, or alternatively, the singulation tool set 125 may include a router tool or a laser tool that removes the semiconductor package from a strip or a panel of an organic substrate material, among other examples. In some implementations, the example environment 100 includes a plurality of types of such tools as part of the singulation tool set 125.

The die-attach tool set 130 includes one or more tools that are capable of attaching the one or more IC dies to the interposer, the leadframe, and/or the strip of the organic substrate material, among other examples. The die-attach tool set 130 may include a pick-and-place tool, a taping tool, a laminating tool, a reflow tool (e.g., a furnace), a soldering tool, or an epoxy dispense tool, among other examples. In some implementations, the example environment 100 includes a plurality of types of such tools as part of the die-attach tool set 130.

The encapsulation tool set 135 includes one or more tools that are capable of encapsulating the one or more IC dies (e.g., the one or more IC dies attached to the interposer, the leadframe, or the strip of organic substrate material). For example, the encapsulation tool set 135 may include a molding tool that encapsulates the one or more IC dies in a plastic molding compound. Additionally, or alternatively, the encapsulation tool set 135 may include a dispense tool that dispenses an epoxy polymer underfill material between the one or more IC dies and an underlying surface (e.g., the interposer or the strip of organic substrate material, among other examples). In some implementations, the example environment 100 includes a plurality of types of such tools as part of the encapsulation tool set 135.

The PCB tool set 140 incudes one or more tools that are capable of forming a PCB having one or more layers of electrically-conductive traces. The PCB tool set 140 may form a type of PCB, such as a single layer PCB, a multi-layer PCB, or a high density interconnect (HDI) PCB, among other examples. In some implementations, the PCB tool set 140 forms the interposer and/or the substrate. The PCB tool set 140 may include a laminating tool, a plating tool, a photoengraving tool, a laser cutting tool, a pick-and-place tool, an etching tool, a dispense tool, and/or a curing tool (e.g., a furnace) among other examples. In some implementations, the example environment 100 includes a plurality of types of such tools as part of the PCB tool set 140.

The SMT tool set 145 includes one or more tools that are capable of mounting the semiconductor package to a circuit board (e.g., a central processing unit (CPU) PCB, a memory module PCB, an automotive circuit board, and/or a display system board, among other examples). The SMT tool set 145 may include a stencil tool, a solder paste printing tool, a pick-and-place tool, a reflow tool (e.g., a furnace), and/or an inspection tool, among other examples. In some implementations, the example environment 100 includes a plurality of types of such tools as part of the SMT tool set 145.

The finished goods tool set 150 includes one or more tools that are capable of preparing a final product including the semiconductor package for shipment to a customer. The finished goods tool set 150 may include a tape-and-reel tool, a pick-and-place tool, a carrier tray stacking tool, a boxing tool, a drop-testing tool, a carousel tool, a controlled-environment storage tool, and/or a sealing tool, among other examples. In some implementations, the example environment 100 includes a plurality of types of such tools as part of the finished goods tool set 150.

The transport tool set 155 includes one or more tools that are capable of transporting work-in-process (WIP) between the semiconductor processing tools 105-150. The transport tool set 155 may be configured to accommodate one or smore transport carriers such a wafer transport carrier (e.g., a wafer cassette or a front opening unified pod (FOUP), among other examples), a die carrier transport carrier (e.g., a film frame, among other examples), and/or a package transport carrier (e.g., a joint electron device engineering (JEDEC) tray or a carrier tape reel, among other examples). The transport tool set 155 may also be configured to transfer and/or combine WIP amongst transport carriers. The transport tool set 155 may include a pick-and-place tool, a conveyor tool, a robot arm tool, an overhead hoist transport (OHT) tool, an automated materially handling system (AMHS) tool, and/or another type of tool. In some implementations, the example environment 100 includes a plurality of types of such tools as part of the transport tool set 155.

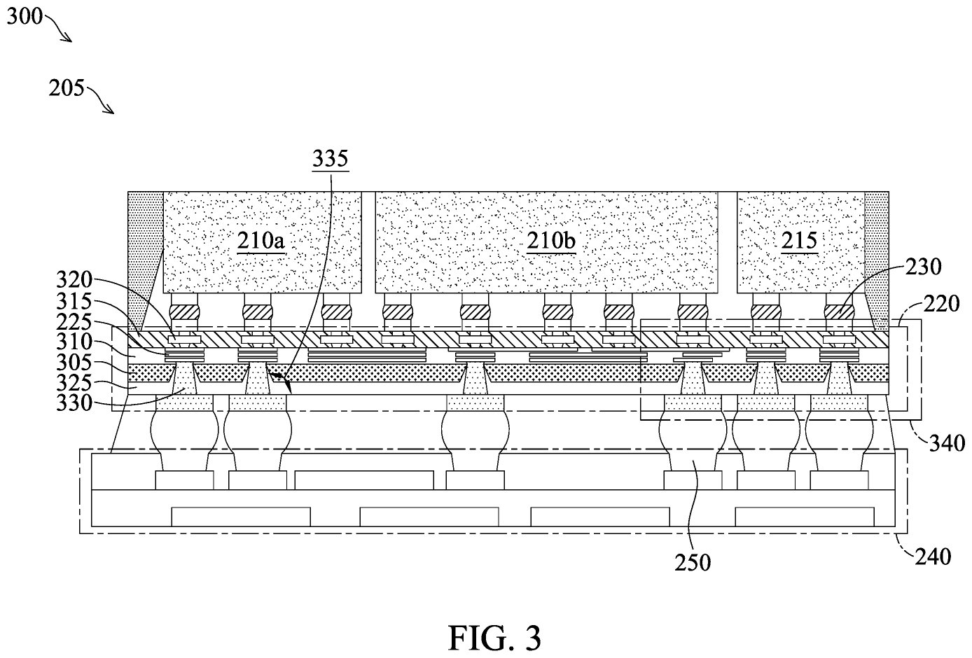

One or more of the semiconductor processing tool sets 105-150 may perform a combination of operations. For example, and as described in greater detail in connection with FIGS. 3-8E and elsewhere herein, the combination of operations includes forming one or more redistribution layers that include one or more electrically-conductive traces on a top surface of a silicon substrate. The combination of operations includes forming a passivation layer including pad structures over the one or more redistribution layers. The combination of operations includes forming a buffer layer comprising an inorganic material on a bottom surface of the silicon substrate. The combination of operations includes forming a set of tapered interconnect structures that pass through the buffer layer and the silicon substrate to make electrical contact with the one or more electrically-conductive traces. In some implementations, forming the set of tapered interconnect structures excludes forming the set of tapered interconnect structures using a TSV process.

The number and arrangement of tool sets shown in FIG. 1 are provided as one or more examples. In practice, there may be additional tool sets, different tool sets, or differently arranged tool sets than those shown in FIG. 1. Furthermore, two or more tool sets shown in FIG. 1 may be implemented within a single tool set, or a tool set shown in FIG. 1 may be implemented as multiple, distributed tool sets. Additionally, or alternatively, one or more tool sets of environment 100 may perform one or more functions described as being performed by another tool set of environment 100.

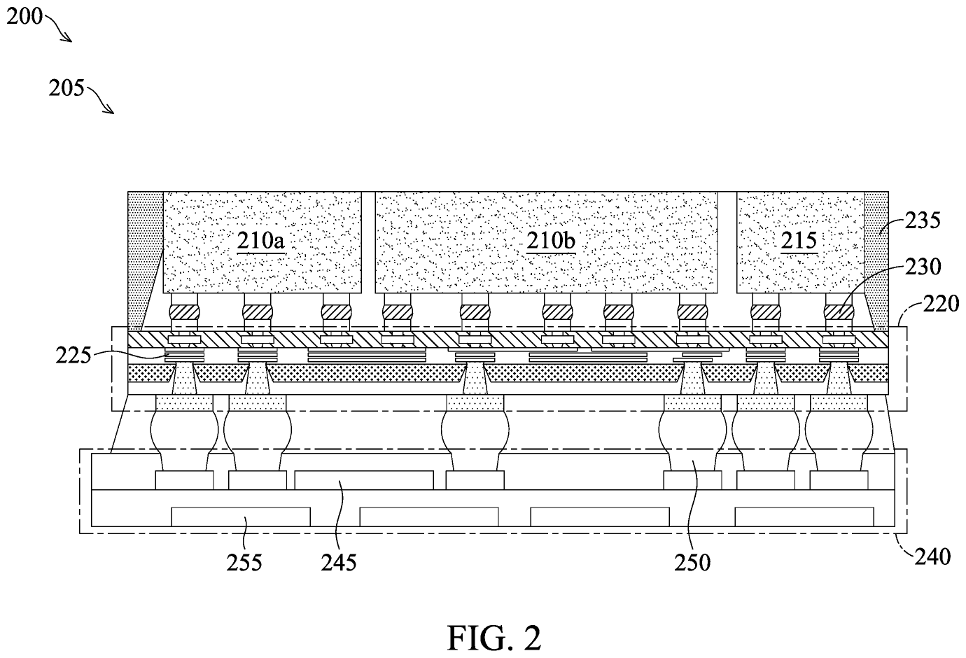

FIG. 2 is a diagram of an example implementation 200 of a semiconductor package 205 described herein. In some implementations, the semiconductor package 205 corresponds to a high-performance computing (HPC) semiconductor package. Furthermore, FIG. 2 represents a side view of the of the semiconductor package 205.

The semiconductor package 205 may include one or more IC dies (e.g., a system-on-chip (SoC) IC die 210, and/or a dynamic random access memory (DRAM) IC die 215, among other examples). The semiconductor package 205 may include an interposer 220 having one or more layers of electrically-conductive traces 225. The interposer 220 may include one or more layers of a dielectric material, such as a ceramic material or a silicon material. In some implementations, the interposer 220 corresponds to a substrate including layers of a glass-reinforced epoxy laminate material and/or a pre-preg material (e.g., a composite fiber/resin/epoxy material), among other examples. Additionally, or alternatively, one or more layers of the interposer 220 may include a buildup film material.

The electrically-conductive traces 225 may include one or more materials such as a gold (Au) material, a copper (Cu) material, a silver (Ag) material, a nickel (Ni) material, a tin (Sn) material, or a palladium (Pd) material, among other examples. In some implementations, the interposer 220 includes one or more conductive vertical access interconnect structures (vias) that connect one or more layers of the electrically-conductive traces 225.

As shown in FIG. 2, the SoC IC die 210 and the DRAM IC die 215 are connected (e.g., mounted) to the interposer 220 using a plurality of interconnect structures 230. The interconnect structures 230 may include one or more combinations of a stud, a pillar, a bump, or a solderball, among other examples. The interconnect structures 230 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The interconnect structures 230 may connect lands (e.g., pads) on bottom surfaces of the SoC IC die 210 and the DRAM IC die 215 to lands on a top surface of the interposer 220. In some implementations, the interconnect structures 230 may include one or more electrical connections for signaling (e.g., corresponding lands of the SoC IC die 210, the DRAM IC die 215, and the interposer 220 are electrically connected to respective circuitry and/or traces of the SoC IC die 210, the DRAM IC die 215, and the interposer 220).

In some implementations, the interconnect structures 230 may include one or more mechanical connections for attachment purposes and/or spacing purposes (e.g., corresponding lands of the SoC IC die 210, the DRAM IC die 215, and the interposer 220 are not electrically connected to respective circuitry and/or traces of the SoC IC die 210, the DRAM IC die 215, and the interposer 220). In some implementations, one or more of the interconnect structures 230 may function both electrically and mechanically.

A mold compound 235 may encapsulate one or more portions of the semiconductor package 205, including portions of the SoC IC die 210 and/or the DRAM IC die 215. The mold compound 235 (e.g., a plastic mold compound, among other examples) may protect the SoC IC die 210 and/or the DRAM IC die 215 from damage during manufacturing of the semiconductor package 205 and/or during field use of the semiconductor package 205.

The semiconductor package 205 may include a substrate 240 having one or more layers of electrically-conductive traces 245. The substrate 240 may include one or more layers of a dielectric material, such as a ceramic material or a silicon material. In some implementations, the substrate 240 corresponds to a PCB including layers of a glass-reinforced epoxy laminate material and/or a pre-preg material (e.g., a composite fiber/resin/epoxy material), among other examples. Additionally, or alternatively, one or more layers of the substrate 240 may include a buildup film material.

The electrically-conductive traces 245 may include one or more materials such as a gold (Au) material, a copper (Cu) material, a silver (Ag) material, a nickel (Ni) material, a tin (Sn) material, or a palladium (Pd) material, among other examples. In some implementations, the substrate 240 includes one or more conductive vertical access interconnect structures (vias) that connect one or more layers of the electrically-conductive traces 245.

As shown in FIG. 2, the interposer 220 is connected (e.g., mounted) to the substrate 240 using a plurality of connection structures 250. The connection structures 250 may include one or more combinations of a stud, a pillar, a bump, or a solderball, among other examples. In some implementations, the connection structures 250 correspond to controlled collapse chip connection (C4) interconnect structures. The connection structures 250 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 250 may connect lands (e.g., pads) on a bottom surface of the interposer 220 to lands on a top surface of the substrate 240. In some implementations, the connection structures 250 may include one or more electrical connections for signaling (e.g., corresponding lands of the interposer 220 and the substrate 240 are electrically connected to respective circuitry and/or traces of the interposer 220 and the substrate 240). In some implementations, the connection structures 250 may include or more mechanical connections for attachment purposes and/or spacing purposes (e.g., corresponding lands of the interposer 220 and the substrate 240 are not electrically connected to respective circuitry and/or traces of the interposer 220 and the substrate 240). In some implementations, one or more of the connection structures 250 may function both electrically and mechanically.

The semiconductor package 205 may include a plurality of pads 255 on a bottom surface of the substrate 240. The pads 255 may be plated with one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free). In some implementations, the pads 255 may correspond to connection points for other structures (e.g., other connection structures or wirebond structures, among other examples).

As described in greater detail in connection with FIGS. 3-8E, and elsewhere herein, the semiconductor package 205 includes a multi-layer interposer structure (e.g., the interposer 220). The multi-layer interposer structure includes a passivation layer including pad structures, one or more redistribution layers below the passivation layer including electrically-conductive traces (e.g., the electrically-conductive traces 225), and a silicon layer below the one or more redistribution layers including a set of tapered interconnect structures that pass through the silicon layer and a buffer layer below the silicon layer. In some implementations, at least one of the set of tapered interconnect structures includes an aspect ratio that is lesser relative to an aspect ratio of an interconnect structure formed using a TSV process. The semiconductor package 205 includes an IC die (e.g., the SoC IC dies 210a and 210b, or the DRAM IC die 215, among other examples) electrically and/or mechanically connected to a top surface of the multi-layer interposer structure. The semiconductor package 205 includes a substrate (e.g., the substrate 240) electrically and/or mechanically connected to a bottom surface of the multi-layer interposer structure.

Additionally, or alternatively, the semiconductor package 205 includes a hybrid interposer structure (e.g., the interposer 220). The hybrid interposer structure includes a first portion including an organic interposer having first electrically-conductive traces (e.g., a first set of the electrically-conductive traces 225), a second portion including multiple redistribution layers below the first portion having second electrically-conductive traces (e.g., a second set of the electrically-conductive traces 225), a third portion including a silicon layer below the multiple redistribution layers having a set of generally v-shaped interconnect structures that pass through the silicon layer, and a fourth portion below the third portion including an inorganic material and having a thickness that is lesser relative to a thickness of the third portion. In some implementations, at least one of the set of generally v-shaped interconnect structures includes an aspect ratio that is lesser relative to an interconnect structure formed using a TSV process. The semiconductor package 205 includes an IC die (e.g., the SoC IC die 210 or the DRAM IC die 215, among other examples) electrically and/or mechanically connected to a top surface of the hybrid interposer structure. The semiconductor package 205 includes a substrate (e.g., the substrate 240) electrically and/or mechanically connected to a bottom surface of the hybrid interposer structure.

As indicated above, FIG. 2 is provided as an example. Other examples may differ from what is described with regard to FIG. 2.

FIG. 3 is a diagram of an example implementation 300 described herein. As described in connection with FIGS. 1 and 2, and elsewhere herein, a combination of operations and/or techniques may be used in the example implementation 300. Furthermore, FIG. 3 represents a side view of the semiconductor package 205.

As shown in FIG. 3, the interposer 220 of the semiconductor package 205 corresponds to a multi-layer interposer structure. The interposer 220 includes a silicon layer 305 and redistribution (RDL) layers 310 on a top surface of the silicon layer 305. In some implementations, and as described in connection with FIG. 1, one or more tools of the RDL tool set 105 (e.g., the photolithography tools, the deposition tool, and/or the etch tool, among other examples) may form the RDL layers 310. The RDL layers 310 may include one or more layers of electrically-conductive traces (e.g., the electrically-conductive traces 225) separated by one or more layers of a dielectric material. The electrically-conductive traces may include a copper (Cu) material, among other examples. The one or more layers of the dielectric material may include a polyimide material or a polybenzoxazole (PBO) material, among other examples.

The interposer 220 also includes a passivation layer 315 on a top surface of the RDL layers 310. In some implementations, and as described in connection with FIG. 1, one or more tools of the RDL tool set 105 (e.g., the photolithography tools, the deposition tool, and/or the etch tool, among other examples) may form the passivation layer 315. The passivation layer 315 may include a dielectric material such as a polyimide material, an aluminum oxide (e.g., Al₂O₃) material, among other examples. The passivation layer 315 may further include one or more pad structures 320. The pad structures 320 may be formed from an aluminum (Al) material, copper material, aluminum copper material, among other examples.

A buffer layer 325 is on a bottom surface of the silicon layer 305. In some implementations, and as described in connection with FIG. 1, a tool of the RDL tool set 105 (e.g., the deposition tool of the RDL tool set 105) deposits the buffer layer 325 on the bottom surface of the silicon layer 305. The buffer layer 325 may include an inorganic material such as a silicon nitride (e.g., Si₃N₄) material, a polyimide material, a buildup film material, or a solder resist material, among other examples. In some implementations, the buffer layer 325 protects the interposer 220 (e.g., the silicon layer 305) from mechanical damage during manufacturing. Additionally, or alternatively, the buffer layer 325 may provide electrical isolation to a bottom surface of the silicon layer 305.

FIG. 3 further shows a set of interconnect structures 330 that pass through the buffer layer 325 and the silicon layer 305. The interconnect structures 330 may include a tapered-shape, such as a generally v-shape, or a conical shape, among other examples. In some implementations, a slope or exterior angle 335 of the interconnect structures 330 may be included in a range that is greater relative to a range of a slope or exterior angle of interconnect structures formed using a TSV process. In some implementations, and as described in connection with FIG. 1, one or more tools of the RDL tool set 105 (e.g., the laser tool and the deposition tool, among other examples) may form the interconnect structures 330 using a laser plug process. In some implementations, formation of the interconnect structures 330 may include removing material from the RDL layers 310 to expose the electrically-conductive traces 225. The interconnect structures 330 may make electrical contact with the electrically-conductive traces 225.

In some implementations, the laser plug process includes the laser tool of the RDL tool set 105 forming one or more through-holes by pulsing the laser tool on a bottom-surface of the silicon layer 305 prior to formation of the buffer layer 325 on the bottom surface of the silicon layer 305. In such a case, portions of the buffer layer 325 may be formed as a liner within the one or more through-holes during formation of the buffer layer 325. Forming the liner may include the deposition tool of the RDL tool set 105 selectively forming the buffer layer 325 on the silicon layer 305 and on interior surfaces of the one or more through holes. Additionally, or alternatively, the deposition tool may blanketly deposit the buffer layer 325, after which the etch tool or the laser tool of the RDL tool set 105 may remove portions the buffer layer 325 from the traces or interconnect structures of the RDL layers 310. Forming the one or more through-holes prior to formation of the buffer layer 325 may be applicable in cases where dielectric properties of the silicon layer 305 (or properties of a substitute layer including a material other than silicon) are insufficient for electrical isolation of the interconnect structures 330.

In some implementations, the laser plug process includes the laser tool of the RDL tool 105 set forming the one or more through-holes by pulsing the laser tool on a bottom surface of the buffer layer 325 after formation of the buffer layer 325 on the bottom surface of the silicon layer 305. Forming the one or more through-holes after formation of the buffer layer 325 may be applicable in cases where dielectric properties of the silicon layer 305 are sufficient for electrical isolation of the interconnect structures 330.

In some implementations, the laser plug process includes the plating tool of the RDL tool set 105 depositing (e.g., plating) one or more metal materials within the one or more through-holes to form the interconnect structures 330. The interconnect structures 330, which may alternatively be referred to as plug structures, may include one or more of a gold (Au) material, a copper (Cu) material, a silver (Ag) material, a nickel (Ni) material, a tin (Sn) material, or a palladium (Pd) material, among other examples. Additionally, or alternatively, the interconnect structures 330 may include a combination of such metal materials.

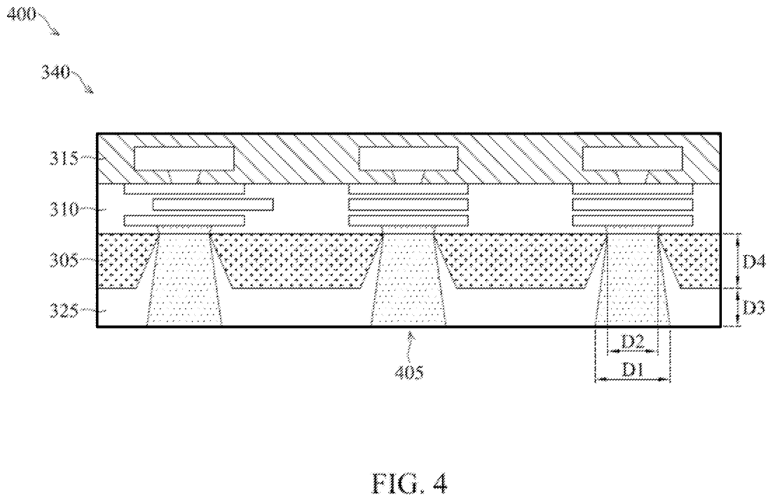

As described in greater detail in connection with FIG. 4 and elsewhere herein, forming the interconnect structures 330 using a laser plug process may accommodate forming the interposer 220 to a thickness that is lesser relative to an interposer formed using a TSV process. Accordingly, an aspect ratio of the interconnect structures 330 may be lesser relative to an aspect ratio of interconnect structures formed using the TSV process. As such, parasitics of the semiconductor package 205 may be reduced to increase a performance of the semiconductor package 205. Additionally, or alternatively, a reduced thickness of the interposer 220 may reduce an overall thickness of the semiconductor package 205 to save space consumed in a computing system including the semiconductor package 205. The reduced thickness of the interposer 220 may also reduce warpage and/or stress within the semiconductor package 205.

As shown in FIG. 3, the semiconductor package 205 includes the interposer 220 having a multi-layer structure. The interposer 220 includes the passivation layer 315 having the pad structures 320 and further includes the RDL layers 310 below the passivation layer 315. The RDL layers 310 include the electrically-conductive traces 225. The interposer 220 further includes the silicon layer 305 below the RDL layers 310 and the buffer layer 325 below the silicon layer 305. A set of tapered interconnect structures (e.g., the interconnect structures 330) pass through the silicon layer 305. The semiconductor package 205 includes an IC die (e.g., the SoC IC die 210a, the SoC IC die 210b, or the DRAM IC die 215, among other examples) that is electrically and/or mechanically connected to a top surface of the interposer 220 (e.g., electrically and/or mechanically connected to the pad structures 320 of the passivation layer 315 using the interconnect structures 230). The semiconductor package 205 further includes the substrate 240 that is electrically and/or mechanically connected to a bottom surface of the interposer 220 (e.g., electrically and/or mechanically connected to the interconnect structures 330 using the connection structures 250).

In some embodiments, the interposer 220 excludes column-shaped interconnect structures that may be formed using the TSV process. As shown in region 340, the interconnect structures 330 formed using the laser plug process include a tapered-shape, such as a generally v-shape or a conical shape, among other examples.

As described in greater detail in connection with FIGS. 4-8E, and elsewhere herein, at least one of the interconnect structures 330 may be formed with the laser plug process to include an aspect ratio (e.g., a ratio of a thickness to a width) that is lesser relative to an aspect ratio of an interconnect structure formed using a TSV process. For example, the laser plug process may form at least one of the interconnect structures 330 to have an aspect ratio of up to approximately 10:1. In contrast, the TSV process may form at least one interconnect structure to have an aspect ratio up to approximately 20:1. Such a difference may lead to an improvement in signal integrity (e.g., reduction in parasitics) in the semiconductor package including the semiconductor package 205 including the interconnect structures interconnect structures 330.

As indicated above, FIG. 3 is provided as an example. Other examples may differ from what is described with regard to FIG. 3.

FIG. 4 is a diagram of an example implementation 400 described herein. As described in connection with FIGS. 1-3, and elsewhere herein, a combination of operations and/or techniques may be used in the example implementation 400. FIG. 4 includes a side view of the region 340 of the semiconductor package 205, including layers of the interposer 220 (e.g., the silicon layer 305, the RDL layers 310, the passivation layer 315, and the buffer layer 325).

As shown in FIG. 4, through-holes 405 have been formed through the silicon layer 305. In the example implementation 400, the through-holes 405 have been formed prior to formation of the buffer layer 325. As further shown in FIG. 4, portions of the buffer layer 325 line sidewalls of the through-holes 405. As part of a deposition process, the buffer layer 325 may be selectively formed on the silicon layer 305 based on differences in materials between the silicon layer 305 (e.g., silicon) and traces of the RDL layers 310 (e.g., an electrically-conductive metal, among other examples) Additionally, or alternatively, portions of the buffer layer 325 may be removed from traces or interconnect structures of the RDL layers 310 using a laser ablation or etch removal process.

The through-holes 405 include a shape having a width D1 at a bottom surface of the buffer layer 325 and a width D2 at a top surface of the silicon layer 305. The shape and dimensions of the through-holes 405 may correspond to a shape and dimensions of plug structures or interconnect structures (e.g., the interconnect structures 230) formed within the through-holes 405.

In some implementations, the width D1 is included in a range of approximately 5 microns to approximately 50 microns. If the width D1 is less than approximately 5 microns, the through-holes 405 may be undersized and may not be compatible with a plating process used to subsequently form interconnect structures (e.g., the interconnect structures 330) within the through-holes 405. Additionally, or alternatively, if the width D1 is less than approximately 5 microns, the subsequently formed interconnect structures may experience electrical reliability issues. If the width D1 is greater than approximately 50 microns, the through-holes 405 may be oversized and the subsequently formed interconnect structures may experience an increase in one or more parasitics (e.g., a capacitance and/or an increased impedance, among other examples). Additionally, or alternatively, if the width D1 is greater than approximately 50 microns, a functionality (e.g., a protective functionality) of the buffer layer 325 may be reduced. However, other values and ranges for the width D1 are within the scope of the present disclosure.

Additionally, or alternatively, the width D2 is included in a range of approximately 5 microns to approximately 20 microns. If the width D2 is less than approximately 5 microns, the through-holes 405 may be undersized and not compatible with a plating process used to subsequently form interconnect structures (e.g., the interconnect structures 330) within the through-holes 405. Additionally, or alternatively, if the width D2 is less than approximately 5 microns, the subsequently formed interconnect structures may experience electrical reliability issues. If the width D2 is greater than approximately 20 microns, the through-holes 405 may be oversized and the subsequently formed interconnect structures may experience an increase in one or more parasitics (e.g., a capacitance and/or an increased impedance, among other examples). However, other values and ranges for the width D2 are within the scope of the present disclosure.

As an example, a width of D1 is greater relative to a width of D2. In such a case, a ratio of the width D1 to the width D2 (e.g., D1:D2) may be included in a range of greater than approximately 1:1 to approximately 2:1. If the ratio D1:D2 is less than 1:1, the through-holes 405 may be incompatible with a plating, filling, or plugging process used to subsequently form interconnect structures (e.g., the interconnect structures 330) within the through-holes 405. Additionally, or alternatively, if the ratio D1:D2 is less than 1:1, an electrical reliability of the subsequently formed interconnect structures within the through-holes 405 may be reduced.

Additionally, or alternatively, if the ratio D1:D2 is equal to 1:1, a technique used for forming the through-holes 405 may correspond to a TSV formation process and increase a length of the subsequently formed interconnect structures within the through-holes 405. The increase in length may lead to increased parasitics (e.g., an increased inductance, among other examples) in the subsequently formed interconnect structures.

Additionally, or alternatively, if the ratio D1:D2 is greater than 2:1, the through-holes 405 may be oversized and the subsequently formed interconnect structures may experience an increase in one or more parasitics (e.g., an increased capacitance and/or an increased impedance, among other examples). Additionally, or alternatively, a functionality (e.g., a protective functionality) of the buffer layer 325 may be reduced. However, other values and ranges for the ratio D1:D2, including a ratio of 1:1, are within the scope of the present disclosure.

In some implementations, a magnitude of the widths D1 and D2 may be controlled through a recipe associated with a tool forming the through-holes 405. For example, if a laser tool of the RDL tool set 105 forms the through-holes 405, a pulsing energy or a pulsing duration of the laser tool may be greater at a depth corresponding to D1 relative to a pulsing energy or a pulsing duration of the laser tool at depth corresponding to D2. Additionally, or alternatively, the lithography tools and the etch tools of the RDL tool set 105 may perform a sequence of patterning and etching operations at different depths to form the through-holes 405 having the widths D1 and D2.

In some implementations, and as shown in FIG. 4, the buffer layer 325 includes a thickness D3. As an example, the thickness D3 may be included in a range of approximately 5 microns to approximately 20 microns. However, other values and ranges for the thickness D3 are within the scope of the present disclosure.

Additionally, or alternatively, the silicon layer 305 includes a thickness D4. As an example, the thickness D4 may be included in a range of approximately 5 microns to approximately 50 microns. However, other values and ranges for the thickness D4 are within the scope of the present disclosure.

In some implementations, a ratio of the thickness D3 to the thickness D4 (D3:D4) is included in a range of up to approximately 1:2. If the ratio D3:D4 is greater than approximately 1:2, the buffer layer 325 may include an excessive amount of material and plug the through-holes 405 prior to subsequent formation of interconnect structures (e.g., the interconnect structures 330). Additionally, or alternatively, a length of the subsequently formed interconnect structures within the through-holes 405 may increase. The increase in length may lead to increased parasitics (e.g., an increased inductance, among other examples) in the subsequently formed interconnect structures. However, other values and ranges for the ratio D3:D4 are within the scope of the present disclosure.

In some implementations, a ratio of the thickness D4 to the width D2 (e.g., D4:D2, an aspect ratio) resulting from the laser plug process is included in a range of up to approximately 10:1. If the ratio D4:D2 is greater than approximately 10:1, a process used to form the through-holes 405 may correspond to a TSV process. Additionally, or alternatively, a length of the subsequently formed interconnect structures within the through-holes 405 may increase. Such an increase in aspect ratio and length may lead to increased parasitics (e.g., increased inductance, among other examples) in the subsequently formed interconnect structures. However, other values and ranges for the ratio D4:D2 are within the scope of the present disclosure.

The dimensions D1-D4, as described in connection with FIG. 4, may correspond to dimensions of interconnect structures formed in the through-holes 405 (e.g., the interconnect structures 330). Additionally, or alternatively, a shape of the through-holes 405 may correspond to a shape of the interconnect structures. The shape may include a tapered shape, such as a generally v-shape or a conical shape, among other examples.

As indicated above, FIG. 4 is provided as an example. Other examples may differ from what is described with regard to FIG. 4.

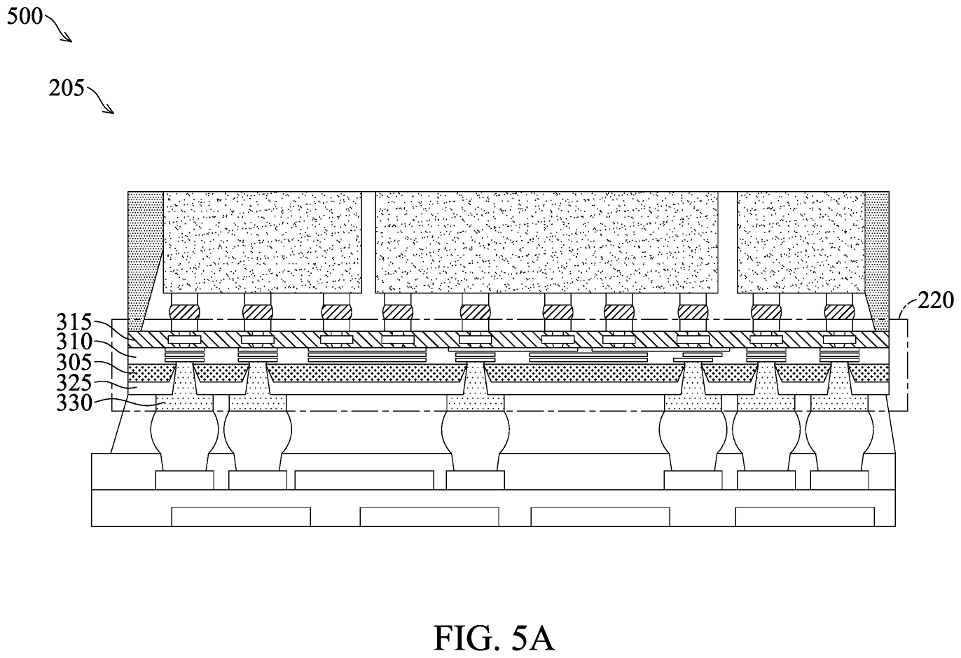

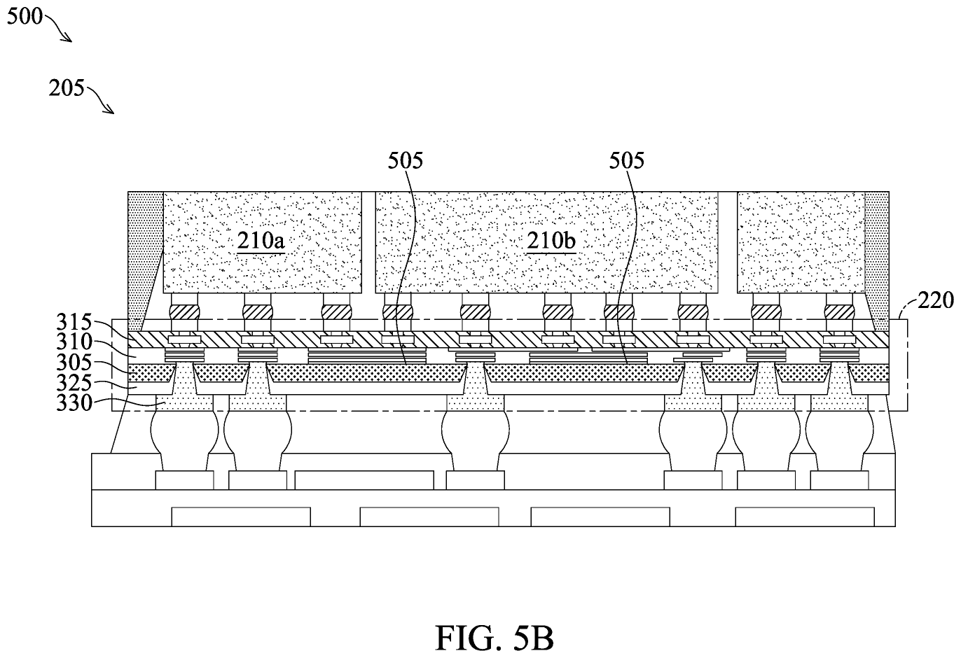

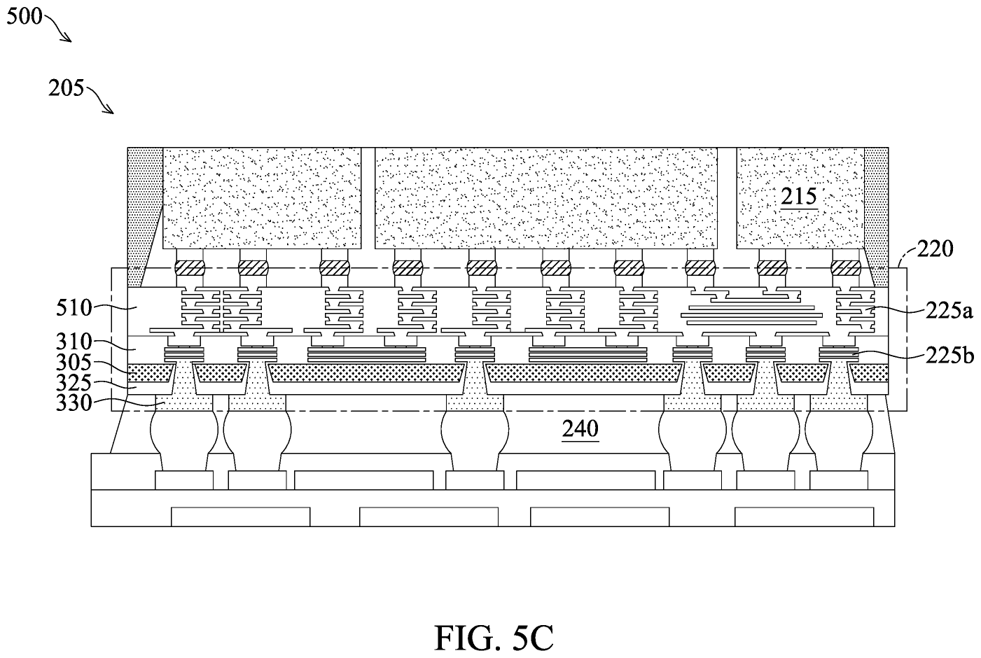

FIGS. 5A-5C include diagrams of one or more example implementations 500 described herein. Example implementation(s) 500 may include one or more variations of the semiconductor package 205 formed using a combination of operations or techniques as described in connection with FIGS. 1-4 and elsewhere herein. FIGS. 5A-5C include side views of the semiconductor package 205.

FIG. 5A shows an example structure of the interposer 220. As shown in FIG. 5A, the structure corresponds to a multi-layer structure including the RDL layers 310 over the silicon layer 305. The structure further includes the passivation layer 315 over the RDL layers 310 and the buffer layer 325 below the silicon layer 305. The structure further includes the interconnect structures 330 passing through the buffer layer 325 and the silicon layer 305.

The structure of FIG. 5A excludes other interconnect structures formed using a TSV process. A signal integrity of signaling in the semiconductor package 205 may be improved using the interconnect structures 330 formed using the laser plug process rather than using a TSV process. Additionally, or alternatively, a cost of the semiconductor package 205 may be reduced by avoiding manufacturing other interconnect structures using the TSV process.

FIG. 5B shows another example structure of the interposer 220. As shown in FIG. 5B, the structure corresponds to a multi-layer structure including the RDL layers 310 over the silicon layer 305. The structure further includes the passivation layer 315 over the RDL layers 310 and the buffer layer 325 below the silicon layer 305. The structure further includes the interconnect structures 330 passing through the buffer layer 325 and the silicon layer 305.

FIG. 5B further shows metal-insulator-metal (MIM) capacitor structures 505 included in the passivation layer 315. In some implementations, the MIM capacitor structures 505 may reduce signaling noise from one or more IC dies (e.g., the SoC IC die 210a and/or the SoC IC die 210b, among other examples) included in the semiconductor package 205.

FIG. 5C shows another example structure of the interposer 220. As shown in FIG. 5C, the structure corresponds to a hybrid interposer structure. The interposer 220 of FIG. 5C includes organic interposer 510 (e.g., a first portion, which may correspond to a PCB) including the electrically-conductive traces 225a (e.g., first electrically-conductive traces). The interposer 220 of FIG. 5C includes the RDL layers 310 (e.g., a second portion) below the organic interposer 510. The electrically-conductive traces 225b (e.g., second electrically conductive traces) are included in the RDL layers 310. The interposer 220 of FIG. 5C includes the silicon layer 305 (e.g., a third portion) below the RDL layers 310 including the interconnect structures 330 (e.g., tapered-shaped, such as generally v-shaped, interconnect structures) that pass through the silicon layer 305. The interposer 220 of FIG. 5C also includes the buffer layer 325 (e.g., a fourth portion, which may include an inorganic material) below the silicon layer 305. In FIG. 5C, the DRAM IC die 215 is electrically and/or mechanically connected to a top surface of the interposer 220 (e.g., the hybrid interposer structure) and the substrate 240 is electrically and/or mechanically connected to a bottom surface of the interposer 220 (e.g., connected to the interconnect structures 230 at a bottom surface of the hybrid interposer structure).

In some implementations, use of the hybrid interposer structure (e.g., including the organic interposer 510) may exhibit favorable signaling characteristics within the semiconductor package 205. As an example, a copper plane in the organic interposer 510 may reduce an electrical resistance for power and ground domains within the semiconductor package 205.

As indicated above, FIGS. 5A-5C are provided as examples. Other examples may differ from what is described with regard to FIGS. 5A-5C.

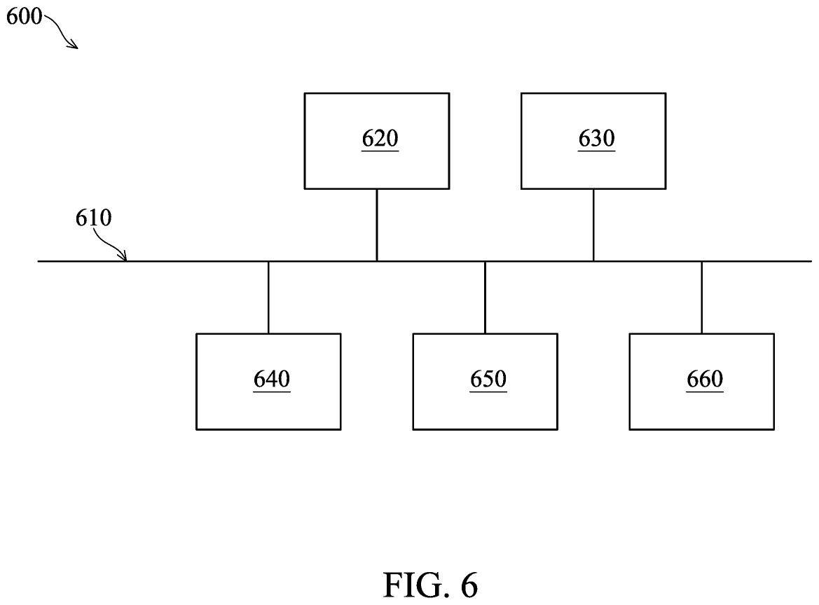

FIG. 6 is a diagram of example components of a device 600, which may correspond to one or more of the semiconductor processing tool sets 105-150. In some implementations, the semiconductor processing tool sets 105-150 include one or more devices 600 and/or one or more components of device 600. As shown in FIG. 6, device 600 may include a bus 610, a processor 620, a memory 630, an input component 640, an output component 650, and a communication component 660.

Bus 610 includes one or more components that enable wired and/or wireless communication among the components of device 600. Bus 610 may couple together two or more components of FIG. 6, such as via operative coupling, communicative coupling, electronic coupling, and/or electric coupling. Processor 620 includes a central processing unit, a graphics processing unit, a microprocessor, a controller, a microcontroller, a digital signal processor, a field-programmable gate array, an application-specific integrated circuit, and/or another type of processing component. Processor 620 is implemented in hardware, firmware, or a combination of hardware and software. In some implementations, processor 620 includes one or more processors capable of being programmed to perform one or more operations or processes described elsewhere herein.

Memory 630 includes volatile and/or nonvolatile memory. For example, memory 630 may include random access memory (RAM), read only memory (ROM), a hard disk drive, and/or another type of memory (e.g., a flash memory, a magnetic memory, and/or an optical memory). Memory 630 may include internal memory (e.g., RAM, ROM, or a hard disk drive) and/or removable memory (e.g., removable via a universal serial bus connection). Memory 630 may be a non-transitory computer-readable medium. Memory 630 stores information, instructions, and/or software (e.g., one or more software applications) related to the operation of device 600. In some implementations, memory 630 includes one or more memories that are coupled to one or more processors (e.g., processor 620), such as via bus 610.

Input component 640 enables device 600 to receive input, such as user input and/or sensed input. For example, input component 640 may include a touch screen, a keyboard, a keypad, a mouse, a button, a microphone, a switch, a sensor, a global positioning system sensor, an accelerometer, a gyroscope, and/or an actuator. Output component 650 enables device 600 to provide output, such as via a display, a speaker, and/or a light-emitting diode. Communication component 660 enables device 600 to communicate with other devices via a wired connection and/or a wireless connection. For example, communication component 660 may include a receiver, a transmitter, a transceiver, a modem, a network interface card, and/or an antenna.

Device 600 may perform one or more operations or processes described herein. For example, a non-transitory computer-readable medium (e.g., memory 630) may store a set of instructions (e.g., one or more instructions or code) for execution by processor 620. Processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry is used instead of or in combination with the instructions to perform one or more operations or processes described herein. Additionally, or alternatively, processor 620 may be configured to perform one or more operations or processes described herein. Thus, implementations described herein are not limited to any specific combination of hardware circuitry and software.

The number and arrangement of components shown in FIG. 6 are provided as an example. Device 600 may include additional components, fewer components, different components, or differently arranged components than those shown in FIG. 6. Additionally, or alternatively, a set of components (e.g., one or more components) of device 600 may perform one or more functions described as being performed by another set of components of device 600.

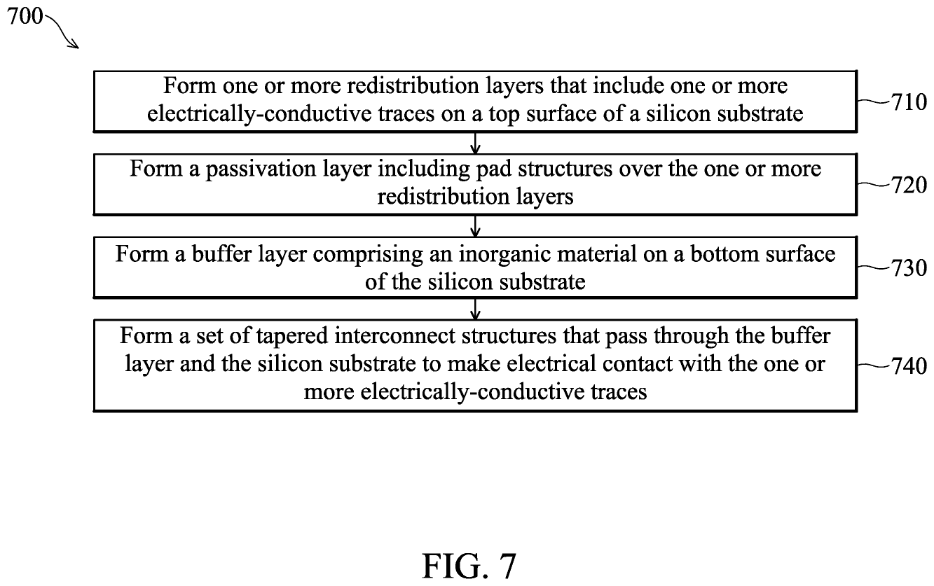

FIG. 7 is a flowchart of an example process associated with forming a semiconductor package described herein. In some implementations, one or more process blocks of FIG. 7 are performed by one or more of the semiconductor processing tool sets 105-150. Additionally, or alternatively, one or more process blocks of FIG. 7 may be performed by one or more components of device 600, such as processor 620, memory 630, input component 640, output component 650, and/or communication component 660.

As shown in FIG. 7, process 700 may include forming one or more redistribution layers that include one or more electrically-conductive traces on a top surface of a silicon substrate (block 710). For example, one or more of the semiconductor processing tool sets 105-150, such as the RDL tool set 105 (e.g., the photolithography tools, the deposition tool, and/or the etch tool of the RDL tool set 105, among other examples) may perform a combination of operations that form one or more redistribution layers 310 that include one or more electrically-conductive traces 225 on a top surface of a silicon layer 305, as described above.

As further shown in FIG. 7, process 700 may include forming a passivation layer including pad structures over the one or more redistribution layers (block 720). For example, one or more of the semiconductor processing tool sets 105-150, such as such as the RDL tool set 105 (e.g., the photolithography tools, the deposition tool, and/or the etch tool of the RDL tool set 105, among other examples) may form a passivation layer 315 including pad structures 320 over the one or more redistribution layers 310, as described above.

As further shown in FIG. 7, process 700 may include forming a buffer layer including an inorganic material on a bottom surface of the silicon substrate (block 730). For example, one or more of the semiconductor processing tool sets 105-150, such as the RDL tool set 105 (e.g., the deposition tool of the RDL tool set 105, among other examples) may perform a combination of operations to form a buffer layer 325 including an inorganic material on a bottom surface of the silicon layer 305, as described above.

As further shown in FIG. 7, process 700 may include forming a set of tapered interconnect structures that pass through the buffer layer and the silicon substrate to make electrical contact with the one or more electrically-conductive traces (block 740). For example, one or more of the semiconductor processing tool sets 105-150, such as the RDL tool set 105 (e.g., the laser tool and the deposition tool of the RDL tool set 105, among other examples) may perform a combination of operations to form a set of tapered interconnect structures (e.g., the interconnect structures 330) that pass through the buffer layer 325 and the silicon layer 305 to make electrical contact with the one or more electrically-conductive traces, as described above. In some implementations, performing the combination of operations may exclude performing a combination of operations corresponding to a TSV process.

Process 700 may include additional implementations, such as any single implementation or any combination of implementations described below and/or in connection with one or more other processes described elsewhere herein.

In a first implementation, forming the set of tapered interconnect structures includes forming through-holes 405 using a laser, and plugging the through-holes 405 using a plating process to form the set of interconnect structures.

In a second implementation, alone or in combination with the first implementation, forming the through-holes 405 includes forming the through-holes by pulsing the laser on a bottom surface of the silicon layer 305 prior to forming the buffer layer 325.

In a third implementation, alone or in combination with one or more of the first and second implementations, forming the set of tapered interconnect structures includes forming the set of tapered interconnect structures to have a first width D1 at a bottom surface of the buffer layer 325 and a second width D2 at a top surface of the silicon substrate, where the second D2 width is lesser relative to the first width D1.

In a fourth implementation, alone or in combination with one or more of the first through third implementations, forming the buffer layer 325 includes forming the buffer layer 325 by depositing a silicon nitride material on the bottom surface of the silicon layer 305.

In a fifth implementation, alone or in combination with one or more of the first through fourth implementations, the set of tapered interconnect structures corresponds to a first set of interconnect structures, and the method further includes attaching a substrate 240 to a bottom surface of the buffer layer 325 using a second set of interconnect structures (e.g., the connection structures 250).

In a sixth implementation, alone or in combination with one or more of the first through fifth implementations, the set of tapered interconnect structures corresponds to a first set of interconnect structures, and the method further includes attaching an IC die (e.g., the SoC IC die 210a, the SoC IC die 210b, or the DRAM IC die 215, among other examples) to a top surface of the passivation layer 315 using a second set of interconnect structures (e.g., the interconnect structures 230).

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

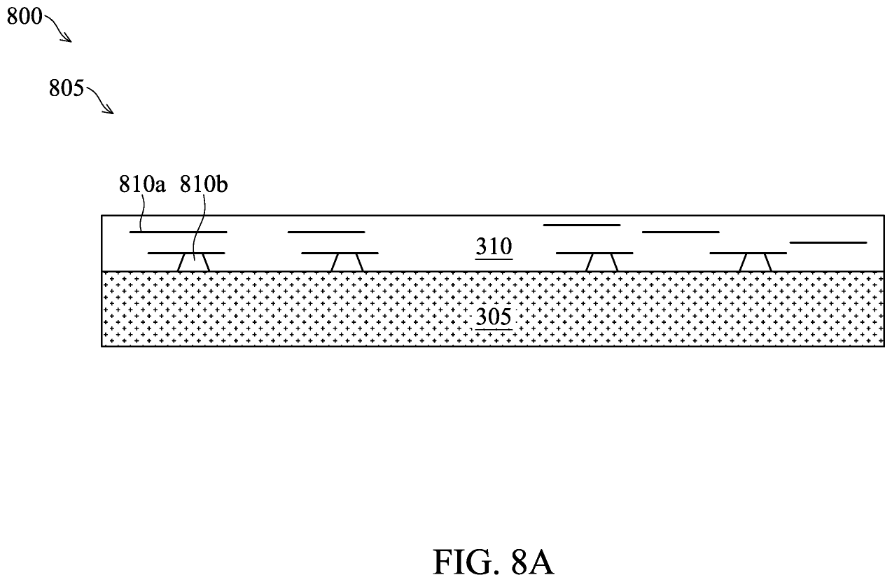

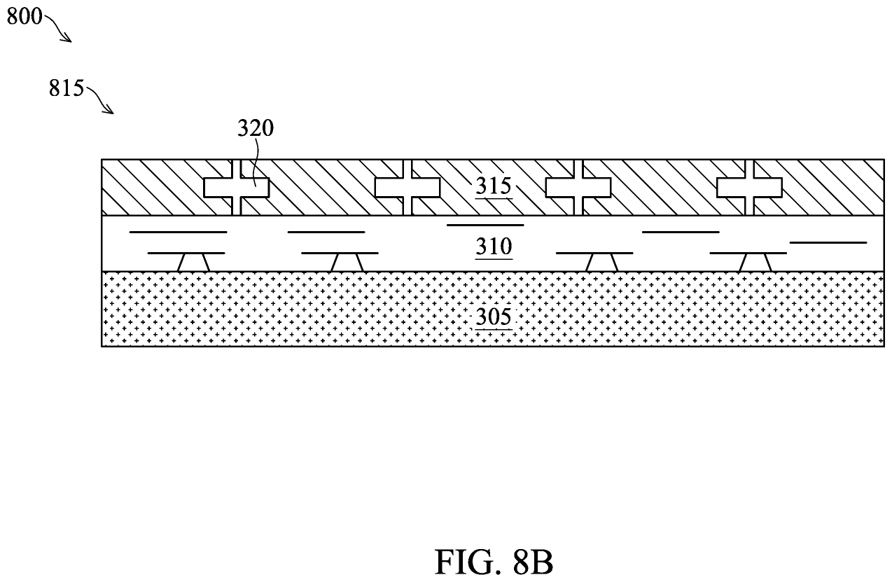

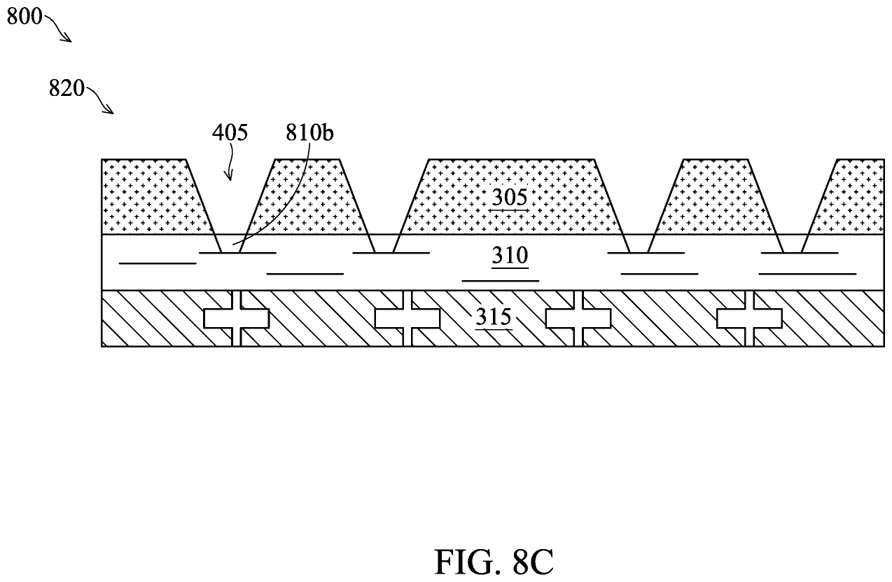

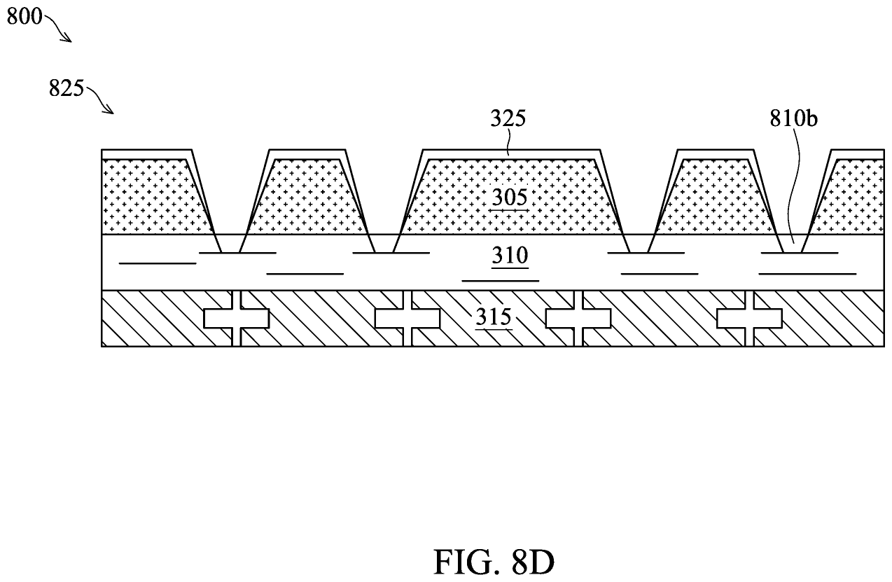

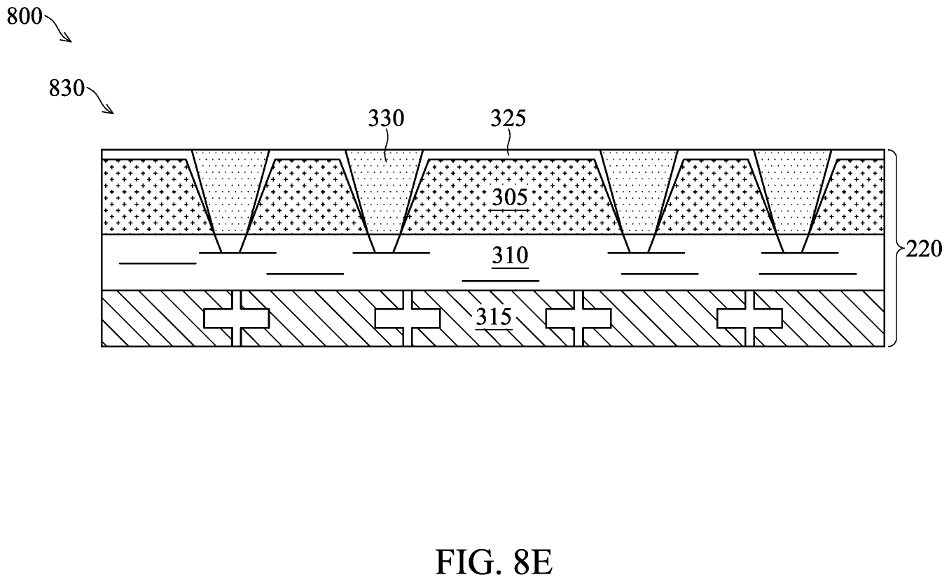

FIGS. 8A-8E are diagrams of an example implementation 800 described herein. The implementation 800 may correspond to a laser plug process, and include a combination of operations that may be performed by the RDL tool set 105 to form the interposer 220 including the interconnect structures 330. The implementation 800 may include one or more operations described in connection the process 700 of FIG. 7.

As shown in FIG. 8A, one or more tools of the RDL tool set 105 (e.g., a combination of the photolithography tools, the deposition tools, and the etch tools of the RDL tool set 105, among other examples) may perform a combination of operations 805 that includes forming the RDL layers 310 over the silicon layer 305. In some implementations, forming the RDL layers 310 includes forming electrically-conductive traces 810a and/or interconnect structures 810b (e.g., electrically-conductive vias or electrically-conductive partial vias, among other examples) within layers of a dielectric material.

As shown in FIG. 8B, one or more tools of the RDL tool set 105 (e.g., a combination of the photolithography tools, the deposition tools, and the etch tools of the RDL tool set 105, among other examples) may perform a combination of operations 815 that includes forming the passivation layer 315 on the RDL layers 310. In some implementations, and as shown in FIG. 8B, forming the passivation layer 315 includes forming one or more pad structures 320 within a dielectric material.

As shown in FIG. 8C, one or more tools of the RDL tool set 105 (e.g., the laser tool of the RDL tool set 105, among other examples) may perform a combination of operations 820 that includes forming the through-holes 405 through a backside (e.g., a bottom surface) of the silicon layer 305. As an example, forming the through-holes 405 may include the laser tool using a pulsing recipe (e.g., a combination of laser power and pulse timing/duration parameters) to control a depth of the through-holes 405 such that the depth corresponds to a surfaces of the interconnect structures 810b. Additionally, or alternatively, the laser tool may use a pulsing recipe that controls the depth of the through-holes 405 such that laser ablates a surface of the interconnect structures 810b. In such a case, ablating the surfaces of the interconnect structures 810b may satisfy a threshold that is acceptable for joining other interconnect structures (e.g., the interconnect structures 330) to the interconnect structures 810b.

As shown in FIG. 8D, one or more tools of the RDL tool set 105 (e.g., the deposition tools, the laser tool, the etch tools, or the photolithography tools, among other examples) may perform a combination of operations 825 that includes forming the buffer layer 325 (e.g., the buffer layer including the inorganic material) on the bottom surface of the silicon layer 305. In some implementations, forming the buffer layer 325 includes a deposition tool selectively depositing the buffer layer 325 on the bottom surface of the silicon layer 305 (and on interior surfaces of the through-holes 405) using a CVD technique, a PVD technique, or another similar technique. Additionally, or alternatively, the combination of operations 825 may include the laser tool or the etch tool removing portions of the buffer layer 325 from surfaces of the interconnect structures 810.

As shown in FIG. 8E, one or more tools of the RDL tool set 105 (e.g., the photolithography tools, the etch tools, and the deposition tools, among other examples) may perform a combination of operations 830 that includes forming the interconnect structures 330 as part of the interposer 220. In some implementations, the combination of operations 830 includes a deposition tool using a plating technique to form the interconnect structures 330 in the through-holes 405.

As indicated above, FIGS. 8A-8E are provided as examples. Other examples may differ from what is described with regard FIGS. 8A-8E, and include additional operations, fewer operations, differently arranged operations, different structures, or different materials than those described in connection with FIGS. 8A-8E

Some implementations herein describe a semiconductor package. The semiconductor package, which may correspond to an HPC semiconductor package, includes an interposer. The interposer includes tapered interconnect structures formed using a laser plug process. The tapered interconnect structures may include a length that is lesser relative to a length of the column-shaped interconnect structures formed using a TSV process. Such a length reduces a thickness of the interposer and reduces a length of electrical connections through the interposer.

In this way, a signal integrity may be increased and parasitics of the semiconductor package including the tapered interconnect structures may be reduced to increase a performance of the semiconductor package. Additionally, the reduced thickness of the interposer may reduce an overall thickness of the semiconductor package to save space consumed by the semiconductor package in a computing system.

As described in greater detail above, some implementations described herein provide a semiconductor package. The semiconductor package includes a multi-layer interposer structure. The multi-layer interposer structure includes a passivation layer including pad structures, one or more redistribution layers below the passivation layer including electrically-conductive traces, and a silicon layer below the one or more redistribution layers including a set of tapered interconnect structures that pass through the silicon layer a buffer layer below the silicon layer. In some implementations, at least one of the set of tapered interconnect structures includes an aspect ratio that is lesser relative to an aspect ratio of an interconnect structure formed using a TSV process. The semiconductor package includes an IC die electrically and/or mechanically connected to a top surface of the multi-layer interposer structure. The semiconductor package includes a substrate electrically and/or mechanically connected to a bottom surface of the multi-layer interposer structure.

As described in greater detail above, some implementations described herein provide a semiconductor package. The semiconductor package includes a hybrid interposer structure. The hybrid interposer structure includes a first portion including an organic interposer having first electrically-conductive traces, a second portion including multiple redistribution layers below the first portion having second electrically-conductive traces, a third portion including a silicon layer below the multiple redistribution layers having a set of generally v-shaped interconnect structures that pass through the silicon layer, and a fourth portion below the third portion including an inorganic material and having a thickness that is lesser relative to a thickness of the third portion. In some implementations, at least one of the set of generally v-shaped interconnect structures includes an aspect ratio that is lesser relative to an interconnect structure formed using a TSV process. The semiconductor package includes an integrated circuit die electrically and/or mechanically connected to a top surface of the hybrid interposer structure. The semiconductor package includes a substrate electrically and/or mechanically connected to a bottom surface of the hybrid interposer structure.

As described in greater detail above, some implementations described herein provide a method. The method includes forming one or more redistribution layers that include one or more electrically-conductive traces on a top surface of a silicon substrate. The method includes forming a passivation layer including pad structures over the one or more redistribution layers. The method includes forming a buffer layer including an inorganic material on a bottom surface of the silicon substrate. The method includes forming a set of tapered interconnect structures that pass through the buffer layer and the silicon substrate to make electrical contact with the one or more electrically-conductive traces. In some implementations, forming the set of tapered interconnect structures excludes forming the set of tapered interconnect structures using a TSV process.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a multi-layer interposer structure comprising:
a passivation layer including pad structures;
one or more redistribution layers below the passivation layer including electrically-conductive traces;
a silicon layer below the one or more redistribution layers including a set of tapered interconnect structures that pass through the silicon layer,
wherein at least one of the set of tapered interconnect structures includes an aspect ratio that is lesser relative to an aspect ratio of an interconnect structure formed using a through-silicon via process; and
a buffer layer below the silicon layer;
an integrated circuit die electrically and/or mechanically connected to a top surface of the multi-layer interposer structure; and
a substrate electrically and/or mechanically connected to a bottom surface of the multi-layer interposer structure.

2. The semiconductor package of claim 1, wherein a ratio of a width of one or more of the set of tapered interconnect structures at a bottom surface of the buffer layer to a width of one or more of the tapered interconnect structures at a top surface of the silicon layer is included in a range of greater than 1:1 to approximately 2:1.

3. The semiconductor package of claim 1, wherein a ratio of a thickness of the silicon layer to a width of one or more of the set of tapered interconnect structures at a top surface of the silicon layer is included in a range of up to approximately 10:1.

4. The semiconductor package of claim 1, wherein a ratio of a thickness of the buffer layer to a thickness of the silicon layer is included in a range of up to approximately 1:2.

5. The semiconductor package of claim 1, wherein the buffer layer comprises an inorganic material.

6. The semiconductor package of claim 1, wherein a width of one or more of the set of tapered interconnect structures at a top surface of the silicon layer is greater than or equal to approximately 0.5 microns.

7. The semiconductor package of claim 1, wherein the one or more redistribution layers comprise:
a metal-insulator-metal capacitor structure.

8. A semiconductor package, comprising:
a hybrid interposer structure comprising:
a first portion comprising an organic interposer including first electrically-conductive traces,
a second portion comprising multiple redistribution layers below the first portion including second electrically-conductive traces,
a third portion comprising a silicon layer below the multiple redistribution layers including a set of generally v-shaped interconnect structures that pass through the silicon layer
wherein at least one of the set of generally v-shaped interconnect structures includes an aspect ratio that is lesser relative to an aspect ratio of an interconnect structure formed using a through-silicon via process, and
a fourth portion below the third portion comprising an inorganic material and having a thickness that is lesser relative to a thickness of the third portion;
an integrated circuit die electrically and/or mechanically connected to a top surface of the hybrid interposer structure; and
a substrate electrically and/or mechanically connected to a bottom surface of the hybrid interposer structure.

9. The semiconductor package of claim 8, wherein the organic interposer corresponds to a printed circuit board.

10. The semiconductor package of claim 8, wherein the silicon layer excludes one or more column-shaped interconnect structures.

11. The semiconductor package of claim 8, wherein one or more of the set of v-shaped interconnect structures that pass through the silicon layer comprises:
a plug structure comprising one or more metal materials.

12. The semiconductor package of claim 11, wherein the one or more metal materials comprise:
a gold material, a copper material, a silver material, a nickel material, a tin material, a palladium material, or a combination thereof.

13. The semiconductor package of claim 8, wherein the fourth portion comprises:
one or more of a buildup film material, a polyimide material, or a solder resist material.

14. A method, comprising:
forming one or more redistribution layers that include one or more electrically-conductive traces on a top surface of a silicon substrate;
forming a passivation layer including pad structures over the one or more redistribution layers;
forming a buffer layer comprising an inorganic material on a bottom surface of the silicon substrate; and
forming a set of tapered interconnect structures that pass through the buffer layer and the silicon substrate to make electrical contact with the one or more electrically-conductive traces,
wherein forming the set of tapered interconnect structures excludes using a through-silicon via process.

15. The method of claim 14, wherein forming the set of tapered interconnect structures comprises:
forming through-holes using a laser; and
plugging the through-holes using a plating process to form the set of interconnect structures.

16. The method of claim 15, wherein forming the through-holes comprises:
forming the through-holes by pulsing the laser on a bottom surface of the silicon substrate prior to forming the buffer layer.

17. The method of claim 15, wherein forming the set of tapered interconnect structures comprises:
forming the set of tapered interconnect structures to have a first width at a bottom surface of the buffer layer and a second width at a top surface of the silicon substrate,
wherein the second width is lesser relative to the first width.

18. The method of claim 14, wherein forming the buffer layer comprises:
forming the buffer layer by depositing a silicon nitride material on the bottom surface of the silicon substrate.

19. The method of claim 14, wherein the set of tapered interconnect structures corresponds to a first set of interconnect structures; and
wherein the method further comprises:
attaching a substrate to a bottom surface of the buffer layer using a second set of interconnect structures.

20. The method of claim 14, wherein the set of tapered interconnect structures corresponds to a first set of interconnect structures; and
wherein the method further comprises:
attaching an integrated circuit die to a top surface of the passivation layer using a second set of interconnect structures.
